(19) United States
(12) Patent Application Publication
(10) Pub. No.: US 2013/0293752 A1
(43) Pub. Date: Nov. 7, 2013

(54) EXPOSURE TIME SELECTION USING STACKED-CHIP IMAGE SENSORS

(71) Applicant: APTINA IMAGING CORPORATION, George Town (KY)

(72) Inventors: Honghong Peng, San Jose, CA (US); Brian Keelan, Boulder Creek, CA (US)

(73) Assignee: Aptina Imaging Corporation, George Town (KY)

(21) Appl. No.: 13/875,549

(22) Filed: May 2, 2013

Related U.S. Application Data
(60) Provisional application No. 61/641,832, filed on May 2, 2012.

(51) Int. Cl. H04N 5/353

(52) U.S. Cl. CPC H04N 5/353
USPC 348/295

(57) ABSTRACT

Imaging systems may be provided with stacked-chip image sensors. A stacked-chip image sensor may include a vertical chip stack that includes an array of image pixels and processing circuitry. The image pixel array may be coupled to the processing circuitry through an array of vertical metal interconnects. The image pixel array may be partitioned into image pixel sub-arrays configured to capture image data using one or more integration times. The processing circuitry may determine motion information for the image data captured by each pixel sub-array and may determine integration times for each pixel sub-array. The pixel sub-arrays may capture additional image data using the determined integration times. The additional image data may be combined to generate final image frames having short integration pixel values and long integration pixel values. The processing circuitry may output the final image frames to off-chip image processing circuitry.

This application claims the benefit of provisional patent application No. 61/641,832, filed May 2, 2012, which is hereby incorporated by reference herein in their entireties.

### BACKGROUND

This relates generally to imaging systems, and more particularly, to imaging systems with stacked-chip image sensors.

Image sensors are commonly used in imaging systems such as cellular telephones, cameras, and computers to capture images. In a typical arrangement, an image sensor is provided with an array of image sensor pixels and control circuitry for operating the image sensor pixels. In a conventional imaging system the control circuitry is laterally separated from the image sensor pixels on a silicon semiconductor substrate. Each row of image sensor pixels typically communicates with the control circuitry along a common metal line on the silicon semiconductor substrate. Similarly, each column of image sensor pixels communicates with the control circuitry along a common metal line.

In this type of system, the rate at which image pixel data can be read out from the image sensor pixels and the rate at which control signals can be supplied to the image sensor pixels can be limited by the use of the shared column and row lines. This type of limitation can limit the rate at which image frames may be captured. Transient image signals such as image light from flashing light sources or from moving objects may be improperly represented in image data due to the limited frame rate. Conventional image sensors capture images using a predetermined integration (exposure) time. When capturing images from real-world scenes using conventional image sensors, images captured from scenes having low light conditions can have insufficient signal-to-noise ratio and images captured from scenes with moving objects can include motion artifacts such as motion blur. It would therefore be desirable to be able to provide improved imaging systems with enhanced image capture and processing efficiency.

### BRIEF DESCRIPTION OF THE DRAWINGS

FIG. 1 is a diagram of an illustrative electronic device having stacked-chip image sensors in accordance with an embodiment of the present invention.

FIG. 2 is a top view of an illustrative image sensor array having a plurality of stacked-chip image sensors each having vertical conductive interconnects for coupling image pixel sub-arrays to control circuitry in accordance with an embodiment of the present invention.

FIG. 3 is a diagram of an illustrative image sensor pixel in accordance with an embodiment of the present invention.

FIG. 4 is a diagram of an illustrative stacked-chip image sensor having an image pixel array in a vertical chip stack that includes analog control circuitry and storage and processing circuitry coupled by vertical metal interconnects in accordance with an embodiment of the present invention.

FIG. 5 is a flow chart of illustrative steps involved in selecting integration times and capturing image data during the selected integration times using pixel sub-arrays in a stacked-chip image sensor in accordance with an embodiment of the present invention.

FIG. 6 is a diagram of a portion of an illustrative image frame containing a moving object in a pixel sub-array in accordance with an embodiment of the present invention.

FIG. 7 is a flow chart of illustrative steps involved in capturing, aligning, and combining image frames to generate a final image having an effective integration time using a stacked-chip image sensor in accordance with an embodiment of the present invention.

FIG. 8 is a flow chart of illustrative steps involved in determining integration times for pixel sub-arrays having image data with and without moving objects using a stacked-chip image sensor to in accordance with an embodiment of the present invention.

FIG. 9 is a flow chart of illustrative steps involved in reading out short integration image data and long integration image data from pixel sub-arrays having image data with and without moving objects in accordance with an embodiment of the present invention.

FIG. 10 is a flow chart of an illustrative step involved in combining long and short integration pixel values to generate a final image frame using a stacked-chip image sensor in accordance with an embodiment of the present invention.

FIG. 11 is a diagram showing how illustrative long and short integration image data may be combined to generate a combined frame having long and short integration pixel values in accordance with an embodiment of the present invention.

FIG. 12 is a diagram showing how illustrative motion-corrected short integration pixel values may be combined with long integration pixel values for generating a combined image frame in accordance with an embodiment of the present invention.

FIG. 13 is a block diagram of a processor system employing the image sensor of FIGS. 1-12 in accordance with an embodiment of the present invention.

### DETAILED DESCRIPTION

Digital camera modules are widely used in imaging systems such as digital cameras, computers, cellular telephones, or other electronic devices. These imaging systems may include image sensors that gather incoming light to capture an image. The image sensors may include arrays of image sensor pixels. The pixels in an image sensor may include photosensitive elements such as photodiodes that convert the incoming light into digital data. Image sensors may have any number of pixels (e.g., hundreds or thousands or more). A typical image sensor may, for example, have hundreds of thousands or millions of pixels (e.g., megapixels).

Each image sensor may be a stacked-chip image sensor having a vertical chip stack that includes an image pixel array die, a control circuitry die, and a digital processing circuitry die. Analog control circuitry on the control circuitry die may be coupled to the image pixel circuitry using vertical conductive paths (sometimes referred to as vertical metal interconnects or vertical conductive interconnects) such as through-silicon vias in a silicon semiconductor substrate. Storage and processing circuitry may be coupled to the analog control circuitry using vertical metal interconnects such as through-silicon vias in the silicon semiconductor substrate. The through-silicon vias may, if desired, be arranged in an array vias. Vertical metal interconnects may be formed at an edge of an image pixel array or throughout an image pixel array. Vertical metal interconnects may be configured to couple rows of image pixels, columns of image pixels, blocks of image pixels, sub-arrays of image pixels, other groups of image pixels, or individual image pixels to the analog control circuitry.

Vertical metal interconnects may be used by the control circuitry to read out image data from image pixels in multiple pixel rows and multiple pixel columns simultaneously thereby increasing the rate at which image data can be obtained from the image pixels in comparison with conventional imaging systems. For example, image data may be captured at a frame rate that is high enough to oversample an oscillating light source such as an LED that oscillates at a frequency of hundreds of cycles per second or to oversample a rapidly moving object such as a baseball or football being thrown by an athlete. Oversampling an oscillating light source may include, for example, capturing image frames at a capture frame rate that is at least twice the number of oscillation cycles per second of the oscillating light source.

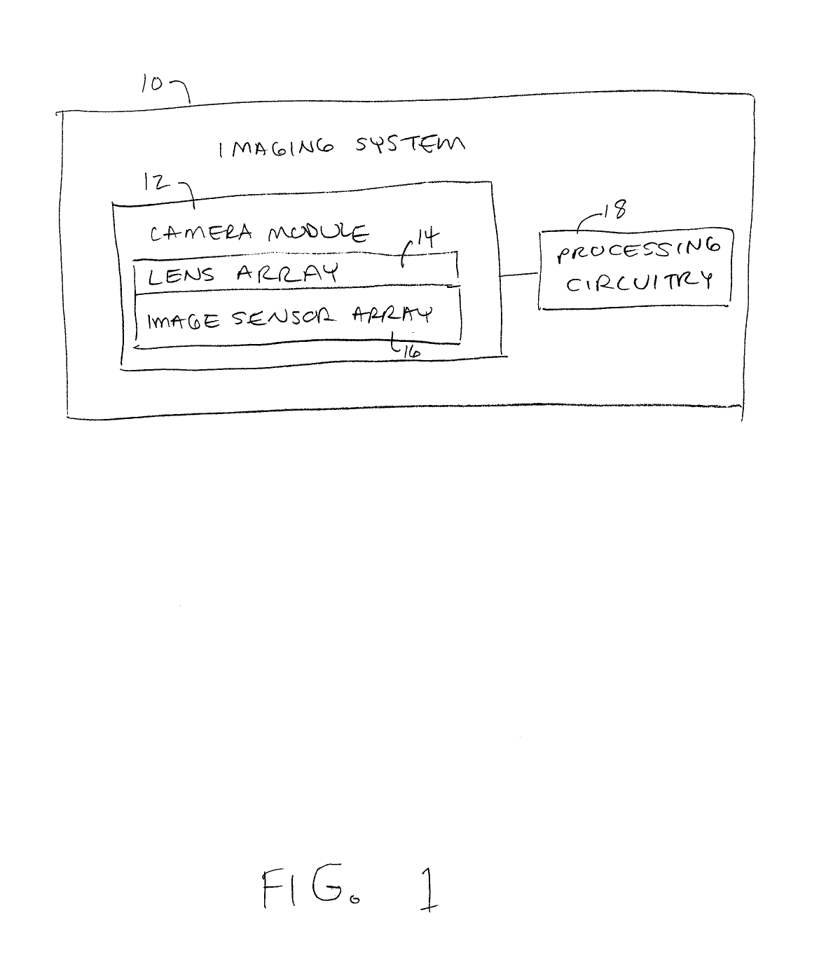

FIG. 1 is a diagram of an illustrative imaging system that uses a stacked-chip image sensor to capture images at a high frame rate in comparison with conventional planar imaging systems. Imaging system 10 of FIG. 1 may be a portable imaging system such as a camera, a cellular telephone, a video camera, or other imaging device that captures digital image data. Camera module 12 may be used to convert incoming light into digital image data. Camera module 12 may include an array of lenses 14 and a corresponding array of stacked-chip image sensors 16. Lenses 14 and stacked-chip image sensors 16 may be mounted in a common package and may provide image data to processing circuitry 18.

Processing circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured and processed by camera module 12 may, if desired, be further processed and stored using processing circuitry 18. Processed image data may, if desired, be provided to external equipment (e.g., a computer or other device) using wired and/or wireless communications paths coupled to processing circuitry 18.

Image sensor array 16 may contain an array of individual stacked-chip image sensors configured to receive light of a given color by providing each stacked-chip image sensor with a color filter. The color filters that are used for image sensor pixel arrays in the image sensors may, for example, be red filters, blue filters, and green filters. Each filter may form a color filter layer that covers the image sensor pixel array of a respective image sensor in the array. Other filters such as white (clear) color filters, ultraviolet filters, dual-band IR cutoff filters (e.g., filters that allow visible light and a range of infrared light emitted by LED lights), etc. may also be used.

An array of stacked-chip image sensors may be formed on one or more semiconductor substrates. With one suitable arrangement, which is sometimes described herein as an example, each vertical layer of a stacked-chip image sensor array (e.g., the image pixel array layer, the control circuitry layer, or the processing circuitry layer) is formed on a common semiconductor substrate (e.g., a common silicon image sensor integrated circuit die). Each stacked-chip image sensor may be identical. For example, each stacked-chip image sensor may be a Video Graphics Array (VGA) sensor with a resolution of 480×640 sensor pixels (as an example). Other types of image sensor may also be used for the image sensors if desired. For example, images sensors with greater than VGA resolution or less than VGA resolution may be used, image sensor arrays in which the image sensors are not all identical may be used, etc. If desired, image sensor array 16 may include a single stacked-chip image sensor.

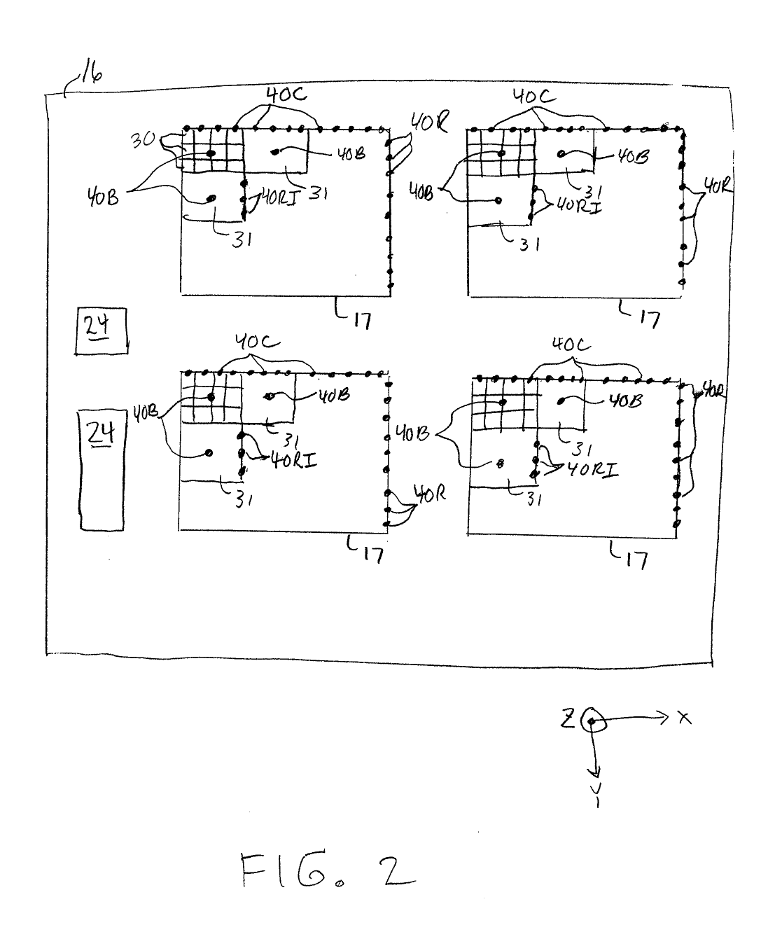

As shown in FIG. 2, image sensor array 16 may include multiple image pixel arrays such as image pixel arrays 17 that are formed on a single integrated circuit die.

In the example of FIG. 2, image sensor array 16 includes four stacked-chip image sensors. However, this is merely illustrative. If desired, image sensor array 16 may include a single stacked-chip image sensor, two stacked-chip image sensors, three stacked-chip image sensors, or more than four stacked-chip image sensors.

Each pixel array 17 may have image sensor pixels such as image pixels 30 that are arranged in rows and columns. Each image sensor pixel array 17 may have any suitable resolution (e.g., 640×480, 4096×3072, etc.). Image sensor pixels 30 may be formed on a planar surface (e.g., parallel to the x-y plane of FIG. 2) of a semiconductor substrate such as a silicon die.

As shown in FIG. 2, each image pixel array 17 may be provided with an array of vertical conductive paths such as conductive interconnects 40 (e.g., metal lines, through-silicon vias, etc. that run perpendicular to the x-y plane of FIG. 2) such as row interconnects 40R, column interconnects 40C, pixel sub-array interconnects 40B, and internal row interconnects 40RI. Row interconnects 40R, column interconnects 40C, pixel sub-array interconnects 40B, and internal row interconnects 40RI may each be configured to couple one or more image pixels 30 to control circuitry (e.g., analog control circuitry) that is vertically stacked with the associated image pixel array (e.g., stacked in the z-direction of FIG. 2).

For example, a row interconnect 40R may couple an associated row of image sensor pixels 30 to control circuitry such as row driver circuitry that is vertically stacked with an image pixel array 17. Row interconnects 40R may be coupled to pixel rows along an edge of image pixel array 17. Each pixel row may be coupled to one of row interconnects 40R. A column interconnect 40C may couple an associated column of image sensor pixels 30 to control circuitry that is vertically stacked with an image pixel array 17. Each image pixel array 17 may be partitioned into a number of image pixel sub-arrays 31. Pixel sub-arrays 31 may include a set of image pixels 30 in image pixel array 17. In the example of FIG. 2, each pixel sub-array 31 includes a group of image pixels 30 arranged in a rectangular pattern. Each pixel sub-array 31 may be, for example, a 4×4 pixel sub-array, an 8×8 pixel sub-array, a 16x16 pixel sub-array, a 32×32 pixel sub-array, etc.

In general, pixel sub-arrays 31 may include image pixels 30 arranged in any desired pattern. If desired, pixel sub-arrays 31 may have a shape that is neither square nor rectangular (e.g., a pixel block may contain 3 pixels of one pixel row, 5 pixels of another pixel row and 10 pixels of a third pixel row, or any arbitrary grouping of adjacent pixels). All pixel sub-arrays 31 may include the same number of pixels 30 or some pixel sub-arrays 31 may include different numbers of pixels than other sub-arrays 31. All pixel sub-arrays 31 may have the same shape (e.g., all sub-arrays 31 may be square or all sub-arrays 31 may be rectangular), or some sub-arrays 31 may have different shapes than other sub-arrays. Each pixel sub-array 31 in a given image pixel array 17 may be coupled via an associated sub-array interconnect 40B to control circuitry such as analog-to-digital conversion circuitry that is vertically stacked with image pixel array 17. An internal row interconnect 40RI may couple a portion of a row of image sensor pixels 30 (e.g., a row of image pixels 30 within a particular pixel sub-array 31) to control circuitry that is vertically stacked with an image pixel array 17. Each pixel row in image pixel array 17 may be coupled to multiple internal row interconnects 40RI. Internal row interconnects 40RI may be coupled to image pixels 30 along an edge of one or more pixel sub-arrays 31 and may couple the pixels 30 of that pixel sub-array 31 to the control circuitry.

Row interconnects 40R, column interconnects 40C, pixel sub-array interconnects 40B, and internal row interconnects 40RI may each be formed from, for example, through-silicon vias that pass from a first silicon semiconductor substrate (e.g., a substrate having an image pixel array) to a second silicon semiconductor substrate (e.g., a substrate having control and readout circuitry for the image pixel array). If desired, image sensor array 16 may include support circuitry 24 that is horizontally (laterally) separated from image pixel arrays 17 on the semiconductor substrate.

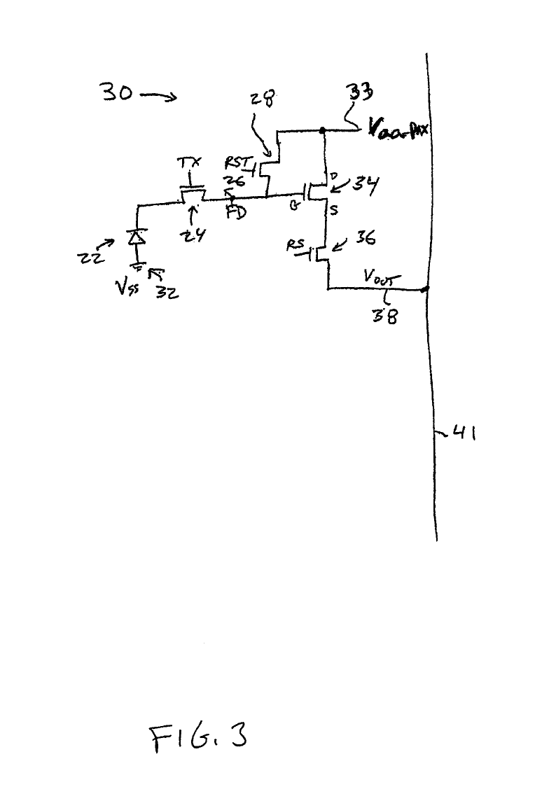

Circuitry in an illustrative image pixel 30 of a given stacked-chip image pixel array 17 is shown in FIG. 3. As shown in FIG. 3, pixel 30 may include a photosensitive element such as photodiode 22. A positive pixel power supply voltage (e.g., voltage Vaa_pix) may be supplied at positive power supply terminal 33. A ground power supply voltage (e.g., Vss) may be supplied at ground terminal 32. Incoming light is gathered by photodiode 22 after passing through a color filter structure. Photodiode 22 converts the light to electrical charge.

Before an image is acquired, reset control signal RST may be asserted. This turns on reset transistor 28 and resets charge storage node 26 (also referred to as floating diffusion FD) to Vaa. The reset control signal RST may then be deasserted to turn off reset transistor 28. After the reset process is complete, transfer gate control signal TX may be asserted to turn on transfer transistor (transfer gate) 24. When transfer transistor 24 is turned on, the charge that has been generated by photodiode 22 in response to incoming light is transferred to charge storage node 26.

Charge storage node 26 may be implemented using a region of doped semiconductor (e.g., a doped silicon region formed in a silicon substrate by ion implantation, impurity diffusion, or other doping techniques). The doped semiconductor region (i.e., the floating diffusion FD) may exhibit a capacitance that can be used to store the charge that has been transferred from photodiode 22. The signal associated with the stored charge on node 26 is conveyed to row select transistor 36 by source-follower transistor 34. If desired, other types of image pixel circuitry may be used to implement the image pixels of sensors 16. For example, each image sensor pixel 30 (see, e.g., FIG. 1) may be a three-transistor pixel, a pin-photodiode pixel with four transistors, a global shutter pixel, etc. The circuitry of FIG. 3 is merely illustrative.

When it is desired to read out the value of the stored charge (i.e., the value of the stored charge that is represented by the signal at the source S of transistor 34), select control signal RS can be asserted. When signal RS is asserted, transistor 36 turns on and a corresponding signal Vout that is representative of the magnitude of the charge on charge storage node 26 is produced on output path 38. In a typical configuration, there are numerous rows and columns of pixels such as pixel 30 in the image sensor pixel array of a given image sensor. A conductive path such as path 41 can be associated with one or more pixels such as a particular sub-array 31 of image pixels 30.

When signal RS is asserted in a given sub-array of pixels, path 41 can be used to route signal Vout from pixels in that sub-array to readout circuitry. Path 41 may, for example, be coupled to one of sub-array interconnects 40B. Image data such as charges collected by photosensor 22 may be passed along one of sub-array interconnects 40B to associated control and readout circuitry that is vertically stacked with image pixel array 17. In this way, multiple pixel sub-arrays 31 in a given pixel array 17 may be read-out in parallel. If desired, image data from two or more sub-arrays 31 in a given pixel array 17 may be subsequently processed in parallel by storage and processing circuitry in stacked-chip image sensor 16.

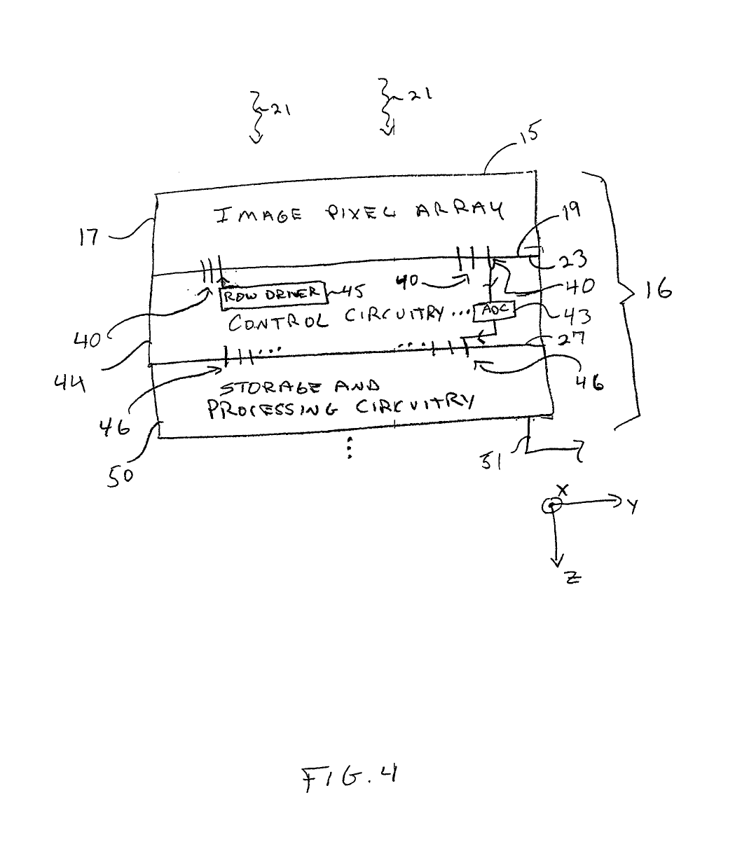

As shown in FIG. 4, an image pixel array such as image pixel array 17 may be formed in a vertical chip stack with analog control and readout circuitry such as control circuitry 44 and storage and processing circuitry such as storage and processing circuitry 50. If desired, image pixel array 17 may be a front-side illuminated (FSI) image pixel array in which image light 21 is received by photosensitive elements through a layer of metal interconnects or may be a backside illuminated (BSI) image pixel array in which image light 21 is received by photosensitive elements formed on a side that is opposite to the side on which the layer of metal interconnects is formed.

Image pixel array 17 may be formed on a semiconductor substrate that is configured to receive image light 21 through a first surface (e.g., surface 15) of the semiconductor substrate. Control circuitry 44 may be formed on an opposing second surface (e.g., surface 19) of the semiconductor substrate. Control circuitry 44 may be formed on an additional semiconductor substrate (semiconductor integrated circuit die) having a surface such as surface 23 that is attached to surface 19 of image pixels array 17. Control circuitry 44 may be coupled to image pixels in image pixel array 17 using vertical conductive paths (vertical conductive interconnects) 40 (e.g., row interconnects 40R, column interconnects 40C, pixel sub-array interconnects 40B, and/or internal row interconnects 40RI of FIG. 2). Vertical conductive interconnects 40 may be formed from metal conductive paths or other conductive contacts that extend through surface 19 and surface 23. As examples, vertical conductive interconnects 40 may include through-silicon vias that extend through surface 19 and/or surface 23, may include microbumps that protrude from surface 19 into control circuitry substrate 44 through surface 23, may include microbumps that protrude from surface 23 into image pixel array substrate 17 through surface 23, or may include any other suitable conductive paths that vertically couple pixel circuitry in image pixel array 17 to control circuitry 44.

Image pixel array 17 may include one or more layers of dielectric material having metal traces for routing pixel control and readout signals to image pixels 30. Vertical conductive interconnects 40 (e.g., row interconnects 40R, column interconnects 40C, pixel sub-array interconnects 40B, and/or internal row interconnects 40RI of FIG. 2) may be coupled to metal traces in image pixel array 17.

Image data such as signal Vout (FIG. 3) may be passed from pixel output paths 40 (FIG. 3) along interconnects 40 from image pixel array 17 to control circuitry 44. Control signals such as reset control signal RST, row/pixel select signal RS, transfer signal TX or other control signals for operating pixels 30 may be generated using control circuitry 44 and passed vertically to pixels 30 in image pixel array 17 along vertical interconnects 40.

Control circuitry 44 may be configured to operate pixels 30 of image pixel array 17. Control circuitry 44 may include row control circuitry (row driver circuitry) 45, bias circuitry (e.g., source follower load circuits), sample and hold circuitry, correlated double sampling (CDS) circuitry, amplifier circuitry, analog-to-digital (ADC) conversion circuitry 43, data output circuitry, memory (e.g., buffer circuitry), address circuitry, etc. Control circuitry 44 may be configured to provide bias voltages, power supply voltages or other voltages to image pixel array 17. Control circuitry 44 may be formed as a stacked layer of image pixel array 17 that is coupled to pixel circuitry of pixel array 17 or may be formed on an additional semiconductor integrated circuit die that is coupled to image pixel array 17 using interconnects 40. Some interconnects 40 may be configured to route image signal data from image pixel array 17 to ADC circuit 43. Digital image data from ADC converter 43 may then be provided to storage and processing circuitry 50. Storage and processing circuitry 50 may, for example, be an image coprocessor (ICOP) chip that is stacked with control circuitry 44.

Image data signals read out using control circuitry 44 from photosensitive elements on image pixel array 17 may be passed from control circuitry 44 to storage and processing circuitry 50 that is vertically stacked (e.g., in direction z) with image pixel array 17 and control circuitry 44 along vertical interconnects such as interconnects 46. Vertical interconnects 46 may include through-silicon vias, microbumps or other suitable interconnects that couple metal lines in control circuitry 44 to metal lines in processing circuitry and storage 50.

Circuitry 50 may be partially integrated into control circuitry 44 or may be implemented as a separated semiconductor integrated circuit that is attached to a surface such as surface 27 of control circuitry 44. Image sensor 16 may include additional vertical conductive interconnects 46 such as metal conductive paths or other conductive contacts that extend through surface 27. As examples, vertical conductive interconnects 46 may include through-silicon vias that extend through surface 27, may include microbumps that protrude from surface 27 into processing circuitry substrate 50, or may include any other suitable conductive paths that vertically couple control circuitry 44 to storage and processing circuitry 50.

Processing circuitry 50 may include one or more integrated circuits (e.g., image processing circuits, microprocessors, storage devices such as random-access memory and non-volatile memory, etc.) and may be implemented using components that are separate from control circuitry 44 and/or that form part of control circuitry 44.

Image data that has been captured by image pixel array 17 (e.g., pixel values) may be processed and stored using processing circuitry 50. Storage and processing circuitry may, for example, process image data from multiple pixel sub-arrays 31 in parallel. Image data may be captured at a capture frame rate using image pixel array 17 and processed using storage and processing circuitry 50. Processed image data may be stored in storage and processing circuitry 50 or may be passed to external circuitry such as circuitry 18 along, for example, path 51. Processed image data may be passed to off-chip processing circuitry 18 at an output frame rate that is lower than the capture frame rate. Multiple image frames captured at the capture frame rate may be combined to form the processed image data that is output from stacked-chip image sensor 16.

Storage and processing circuitry 50 formed in a vertical stack with image pixel array 17 of stacked-chip image sensor 16 may, for example, select a subset of digital image data to use in constructing a final image (e.g., image data from one or more pixel sub-arrays 31), may combine multiple frames that contain transient signals (e.g., image signals from a flashing light or a moving object) to form corrected image frames, may extract image depth information, or may provide processing options to a user of system 10.

FIG. 4 is merely illustrative. If desired, part or all of control circuitry 44 may be formed as a part of image pixel array 17 (e.g., control circuitry such as row driver 45 and ADC 43 may be formed on the same semiconductor substrate as image pixel array 17 in stacked-chip image sensor 16) and/or as a part of storage and processing circuitry 50 (e.g., control circuitry such as row driver 45 and ADC 43 may be formed on the same semiconductor die as storage and processing circuitry 50).

Storage and processing circuitry 50 (sometimes referred to herein as stacked processing circuitry or stacked-chip processing circuitry) may be used to combine image data from red, blue, and green sensors to produce full-color images, may be used to determine image parallax corrections, may be used to produce 3-dimensional (sometimes called stereo) images using data from two or more different sensors that have different vantage points when capturing a scene, may be used to produce increased depth-of-field images using data from two or more image sensors, may be used to adjust the content of an image frame based on the content of a previous image frame, or may be used to otherwise process image data.

Stacked processing circuitry 50 may be configured to perform white balancing, color correction, high-dynamic-range image combination, motion detection, object distance detection, or other suitable image processing on image data that has been passed vertically from control circuitry 44 to processing circuitry 50. Processed image data may, if desired, be provided to external equipment (e.g., a computer, other device, or additional processing circuitry such as processing circuitry 18) using wired and/or wireless communications paths coupled to processing circuitry 50.

Stacked-chip image sensors such as stacked-chip image sensor 16 may capture images from a scene using one or more exposure times (sometimes referred to as integration times). For example, stacked-chip image sensor 16 may capture images having relatively short integration times or relatively long integration times. A short-exposure image captured during a short integration time may better capture details of brightly lit portions of the scene, whereas a long-exposure image captured during a long integration time may better capture details of dark portions of the scene.

In some situations, objects in a scene may move during imaging operations. In this type of situation, a captured image may include motion artifacts such as motion blur.

When capturing images from a scene having moving objects, images captured during shorter integration times may have fewer motion artifacts than images captured during longer integration times. However, images captured during longer integration times may have enhanced signal-to-noise ratio (SNR) relative to images captured during shorter integration times. Processing circuitry on stacked-chip image sensor 16 such as stacked storage and processing circuitry 50 may be used to operate image sensor 16 to capture images using one or more integration times (e.g., charge integration times or effective integration times based on multiple captured image frames) that are based on the content of the scene. For example, processing circuitry 50 may analyze image data captured from a scene to determine exposure times to be used by image pixels 30 for capturing subsequent image data from the scene. For example, stacked processing circuitry 50 may process image data captured from a scene to detect moving objects in the scene. If desired, processing circuitry 50 may determine image statistics such as a signal-to-noise ratio associated with the captured image data for selecting integration times.

Image sensor 16 may be used to generate output images at an output frame rate. Each output image may have image data from particular sub-arrays that has been accumulated during different integration times. In one suitable example, the different integration times may be different effective integration times based on one or more combined image frames that were captured during a capture integration time that is shorter than or equal to the effective integration time. In another suitable example, the different integration times may be individual continuous charge integration times for each sub-array that have been determined based on non-destructive sampling of pixel voltages during charge integrations operations. This type of individually determined continuous charge integration period may help reduce motion artifacts while reducing the read noise associated with multiple image captures. However, this is merely illustrative. If desired, individually determined continuous charge integration periods for each sub-array may be combined with the multiple image capture method described above to minimize read noise while allowing for motion correction operations on multiple captured frames.

In the example of different effective integration times, Stacked-chip image sensor 16 may capture images during a capture integration time. Each image frame captured using the capture integration time may be captured at a high-speed capture frame rate (e.g., 90 frames per second, 120 frames per second, or greater than 120 frames per second). The capture frame rate is inversely proportional to the capture integration time that is used. For example, stacked-chip image sensor 16 may capture image frames at a capture frame rate of 100 frames per second if a stacked-chip image sensor 16 captures image frames using a capture integration time of 10 ms.

In order to improve signal-to-noise ratio of final images, processing circuitry 50 may combine multiple image frames that were captured using the capture integration time. For example, pixel values from image frames captured using the capture integration time may be averaged, summed, or combined using any other desired method. Combined image frames generated by processing circuitry 50 may have an effective integration time. The effective integration time may be greater than or equal to the capture integration time and may be dependent on the number of image frames captured that are combined to generate the combined image frame. For example, the effective integration time may be equivalent to a sum of the capture integration times for each image frame used to generate the combined image frame. As an example, if stacked-chip image sensor 16 captures two image frames with a capture integration time of 8 milliseconds, processing circuitry 50 may combine the two image frames to generate a combined image frame (sometimes referred to as an accumulate-frame or an accumulated frame) having an effective integration time of 16 milliseconds.

In the example of individual charge integration times for each sub-array, processing circuitry 50 may receive samples of image data from each sub-array during charge integration operations, determine a desired integration time for that sub-array, and capture and read out image data using the determined integration times for each sub-array.

In both of these examples, stacked-chip image sensor 16 may be used to capture and process image data from multiple pixel sub-arrays 31 in parallel to generate images having different integration times (e.g., effective integration times or actual integration times) for each pixel sub-array 31 (e.g., based on the image data captured by the associated pixel sub-array 31). For example, sensor 16 may capture images having portions with relatively long effective integration times for pixel sub-arrays 31 having image data without moving objects and portions with relatively short effective integration times for pixel sub-arrays having image data with moving objects.

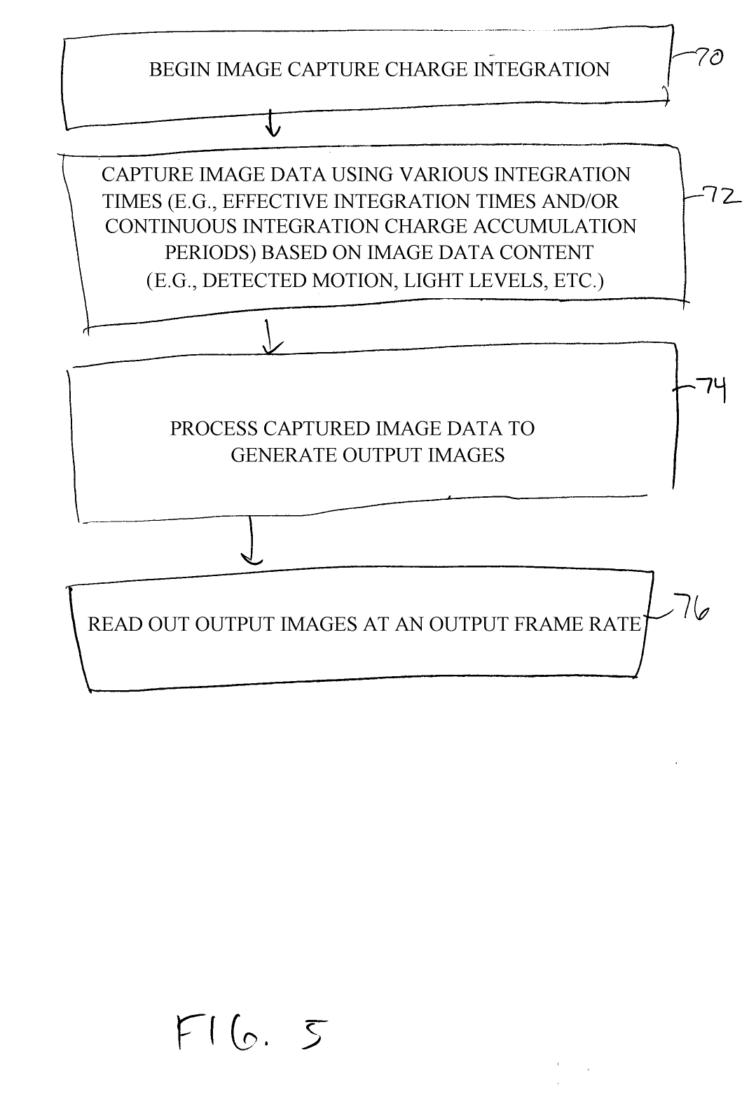

FIG. 5 is a flow chart of illustrative steps that may be used for capturing image data during selected integration times using a stacked-chip image sensor such as stacked-chip image sensor 16 of FIG. 4.

At step 70, image pixel array 17 (e.g., one or more pixel sub-arrays 31 of pixel array 17) in stacked-chip image sensor 16 may begin image capture charge integration. Image data based on the integrated charge may be transferred to stacked processing circuitry 50. For example, image data from each pixel sub-array 31 may be non-destructively sampled from pixel array 17.

At step 72, sensor 16 may be used to capture image data using integration times for each sub-array that are based on image data content for that sub-array. For example, processing circuitry 50 may process image data sampled from pixel sub-arrays 31 while integrating charge in order to determine continuous charge integration times for each pixel sub-array 31. In another example, image sensor 16 may capture image frames at a capture frame rate.

During image capture operations, processing circuitry 50 may analyze a portion of the captured image data to determine image statistics that may be used for determining the integration times. For example, processing circuitry 50 may determine the integration times based on motion detection operations for the captured image data, detected light levels in the captured image data, a signal-to-noise ratio of some or all of the captured image data, or any other desired statistics associated with the captured image data. Each pixel sub-array 31 in pixel array 17 may subsequently capture additional image data (e.g., one or more image frames of pixel values) using a particular integration time for that sub-array.

At step 74, image data may be processed using circuitry 50 to form output image frames. The output image frames may be images that include portions with different integration times (e.g., different effective integration times based on multiple combined image captures or integration times based on individually determined continuous charge integration periods for each sub-array).

In configurations in which different continuous charge integration times were used for each sub-array, processing circuitry 50 may correct the image data for each sub-array using the integration time that was used for that sub-array or processing circuitry 50 may generate metadata containing the integration times for each sub-array.

In configurations in which multiple image frames were captured at a capture frame rate, processing circuitry 50 may receive and analyze each captured image frame. Processing circuitry 50 may store a first captured image frame as an accumulate frame. Processing circuitry 50 may then determine whether each subsequent captured image frame should be combined with the accumulate frame (e.g., based on motion information determined using the subsequent captured image frame and the accumulate frame). If desired, circuitry 50 may combine multiple captured image frames that were captured at the capture frame rate into the accumulate frame to produce an output image (or a portion of the output image) with an effective integration time that is longer than the inverse of the capture frame rate. If desired, circuitry 50 may correct the image data for each sub-array using the effective integration time that was used for that sub-array or processing circuitry 50 may generate metadata containing the effective integration times for each sub-array.

If desired, the effective integration time of the accumulated image frame may be used by image pixel pixels 30 as the effective integration time with which subsequent frames of image data are captured. In another suitable arrangement, stacked processing circuitry 50 may subsequently determine new effective integration times (e.g., a new effective integration time based on the current content of the imaged scene).

At step 76, stacked processing circuitry 50 may output final image frames (e.g., accumulate-frames) from stacked-chip image sensor 16 to off-chip image processing circuitry such as processing circuitry 18 (FIG. 1) at an output frame rate. The output frame rate may be less than the capture frame rate. The output frame rate may be an integer multiple of the capture frame rate (e.g., the capture frame rate may be at least twice the capture frame rate). For example, if the capture frame rate is 60 frames per second, the output frame rate may be 30 frames per second or less. As another example, if the capture frame rate is 90 frames per second or greater, the output frame rate may be 45 frames per second or less. If desired, the output frame rate may be sufficiently low so that the final image frames may be displayed using conventional display systems (e.g., 30 frame per second display systems, 24 frame per second display systems, etc.).

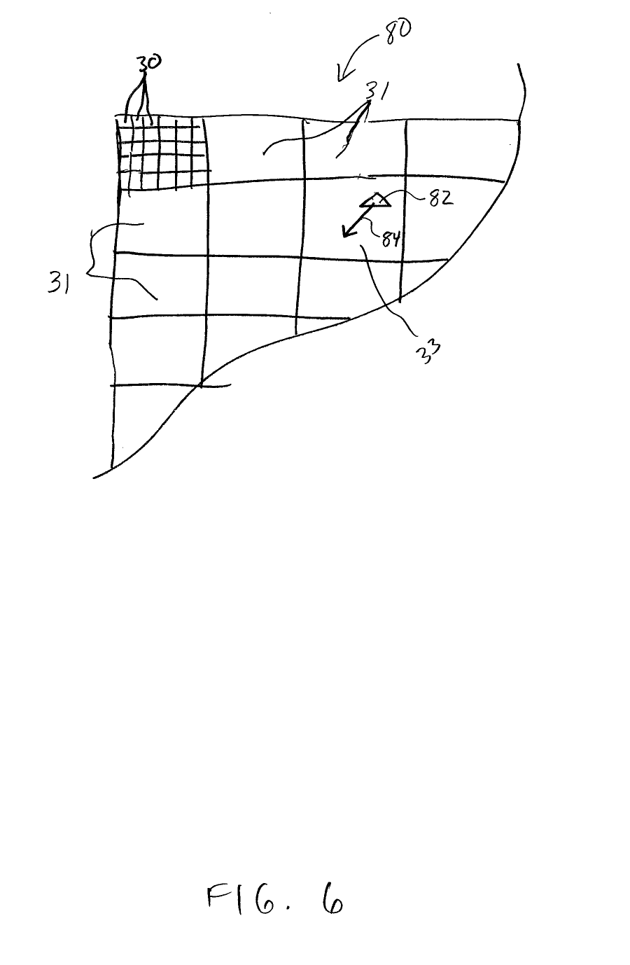

If desired, during image capture operations, stacked storage and processing circuitry 50 may process image data received from pixel sub-arrays 31 to determine whether the image data from one or more sub-arrays 31 include moving objects. FIG. 6 is a diagram that shows how image data captured by a pixel sub-array 31 from a scene may include a moving object that is detected by stacked processing circuitry 50. As shown in FIG. 6, an illustrative image frame 80 may be captured by image pixel array 17. Image frame 80 may include image data from a number of pixel sub-arrays 31 (e.g., image frame 80 may include pixel values generated by image pixels 30 in sub-arrays 31).

Image frame 80 may include an object such as object 82. Object 82 may be partially or completely contained in a particular sub-array 33. Object 82 may be moving in the captured scene, as shown by arrow 84. Stacked processing circuitry 50 may determine that pixel sub-array 33 has a moving object (e.g., processing circuitry 50 may identify object 82 as a moving object). Processing circuitry 50 may detect multiple objects such as object 82 across image frame 80 and may identify which pixel sub-arrays 31 have objects that are moving.

As an example, stacked processing circuitry 50 may determine that object 82 is moving by comparing image frame 80 to a previously captured image frame. Stacked processing circuitry 50 may identify a change in position of object 82 across multiple captured image frames. If desired, processing circuitry 50 may set a reference frame with which to compare subsequently captured frames to characterize motion in an imaged scene. Directional shifted sum of absolute difference (SSAD) metrics may be calculated for a captured image frame such as image frame 80. For example, four directional SSAD metrics (e.g., SSAD values corresponding to rightward camera or object movement, leftward camera or object movement, upward camera or object movement, and downward camera or object movement) may be calculated.

If desired, stacked processing circuitry 50 may characterize the amount of motion in captured image data using a motion metric such as a motion score (sometimes referred to as an SSAD reduction value or an SR value). Stacked processing circuitry 50 may calculate the motion score based on statistical information associated with the image data received from pixel sub-arrays 31. For example, stacked processing circuitry 50 may calculate the motion score based on SSAD values of the captured image data.

To calculate motion scores, processing circuitry 50 may, for example, calculate directional reference SSAD values for each of the four directional SSAD values. The directional reference SSAD values may be calculated by repeating calculations of the four directional SSAD values with the current frame replaced by the reference frame. The calculation of the directional reference SSAD values may sometimes be referred to as performing directional auto-correlation. The reference SSADs may provide baseline reference values (e.g., the reference SSADs may indicate expected SSAD values in the absence of motion). Stacked processing circuitry 50 may compute directional motion scores by subtracting a directional SSAD value from a corresponding reference SSAD value and normalizing the difference by the reference SSAD value (e.g., because directional SSAD values that are close in magnitude to corresponding reference SSAD values reflect scenes with no significant motion).

Stacked processing circuitry 50 may, if desired, calculate a final motion score value from the two directional motion scores with the highest values (e.g., the directional motion scores associated with the two directions that have the most camera or object movement). If the second highest value is greater than zero, the final motion score may be calculated from the difference between the two highest directional motion scores. By subtracting the second highest directional motion score from the highest directional motion score, the final motion score may be calculated to reflect a dominant direction of motion. If the second highest value is less than zero, the final motion score may be set equal to the highest value (e.g., because a second highest motion score that is negative may indicate that no motion is occurring in the direction associated with the second highest motion score). Stacked processing circuitry 50 may use the final motion score to characterize the amount of motion in a given image frame. In general, high motion scores are indicative of scenes with a high amount of movement, whereas low motion scores are indicative of scenes with a low amount of movement.

If desired, stacked processing circuitry 50 may determine integration times (e.g., effective integration times) for pixel sub-arrays 31 based on the calculated motion score between two or more frames captured using the capture integration time. For example, for image data in which the motion score is below a threshold, processing circuitry 50 may instruct image pixel array 17 to capture additional image frames (e.g., additional image frames captured using the capture integration time). Processing circuitry 50 may generate an accumulated image frame using the additional image frames. For example, stacked processing circuitry 50 may average two captured image frames to generate the accumulated image frame. Processing circuitry 50 may subsequently average each additional image frame that is captured by pixel array 17 with the accumulated image frame to increase the signal to noise ratio of the accumulated image frame (assuming that the motion score between any two captured image frames is less than or equal to the threshold). If processing circuitry 50 detects a significant amount of motion between two captured image frames (e.g., if the motion score between the two frames is greater than the threshold), processing circuitry 50 may output the accumulated image frame to off-chip processing circuitry (e.g., so that the outputted image frame includes a higher signal-to-noise ratio than a single captured image frame but does not include any motion artifacts).

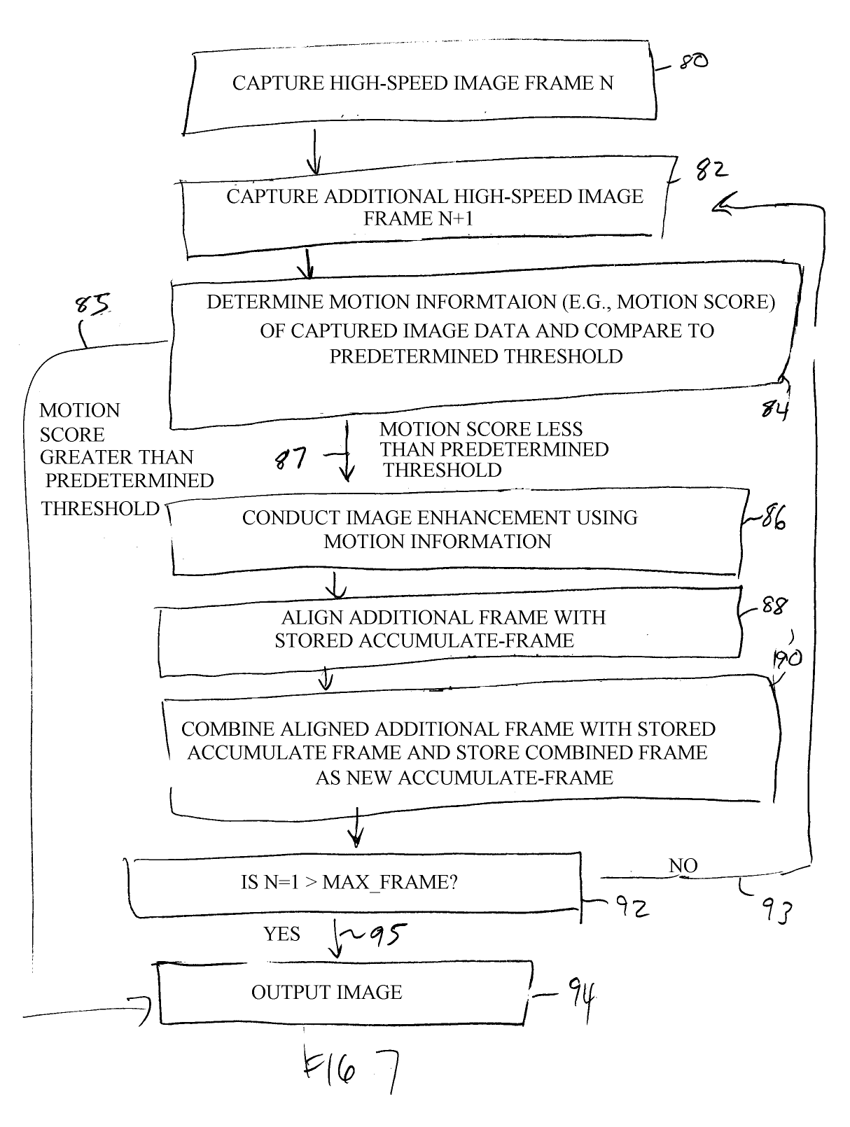

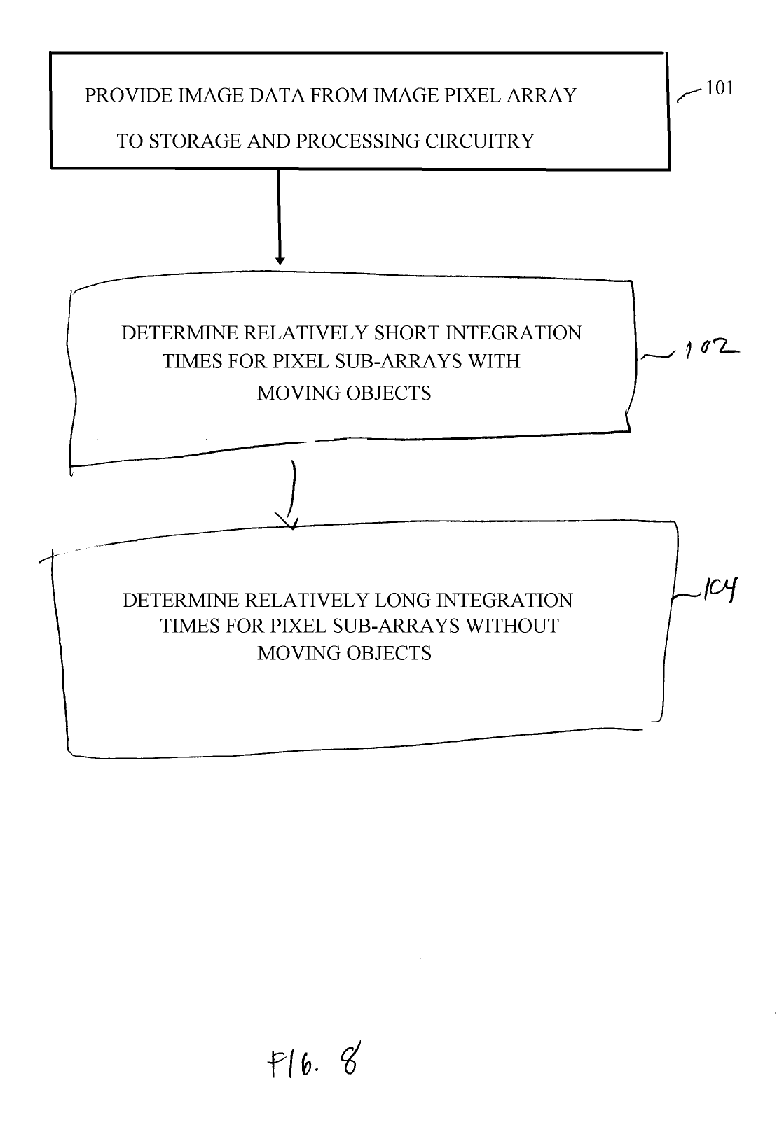

FIGS. 7 and 8 show illustrative steps that may be used in generating images with various integration times. In the example of FIG. 7, different effective integration times are generated for the image by accumulating different numbers of captured image frames at a capture frame rate. In the example of FIG. 8, different charge accumulation periods are determined for each pixel sub-array based on non-destructive sampling of image data from the sub-arrays during charge integration operations.

FIG. 7 is a flow chart of illustrative steps that may be used for capturing image data from a scene and generating an accumulated image frame having an effective integration time using stacked-chip image sensor 16. The steps of FIG. 7 may, for example, be performed by stacked processing circuitry 50 for image data captured using image pixel array 17 or image data captured using one or more pixel sub-arrays 31. The steps of FIG. 7 may, for example, be performed by stacked processing circuitry 50 during step 72 of FIG. 5.

At step 80, image pixel array 17 may capture a high-speed image frame N from a scene. Captured image frame N may be captured during a high-speed capture integration time. For example, captured image frame N may be captured during a capture integration time of 8 milliseconds, 10 milliseconds, less than 8 milliseconds, etc. Captured image frame N may be stored as an initial accumulate frame.

At step 82, image pixel array 17 may capture an additional high-speed image frame N+1. Captured image frame N+1 may be captured using the same capture integration time as captured image frame N. In other words, image frame N and captured image frame N+1 may be captured at a high-speed capture frame rate (e.g., a capture frame rate of 90 frames per second or more). Image frames N and N+1 may be passed to stacked processing circuitry 50 (e.g., image frames N and N+1 may be non-destructively sampled by stacked processing circuitry 50 or may be destructively read out from image pixel array 17 by stacked processing circuitry 50).

At step 84, stacked processing circuitry 50 may determine motion information between captured image frame N and additional captured image frame N+1. For example, processing circuitry 50 may calculate a motion score between captured image frame N and additional captured image frame N+1 (e.g., by comparing image frame N+1 to frame N). Stacked processing circuitry 50 may compare the calculated motion score to a predetermined motion score threshold for motion in the captured image data. The predetermined motion score threshold may, for example, be determined by design requirements, manufacturing requirements, user requirements, regulatory requirements, or any other suitable requirements associated with the amount of motion in the captured image data.

If the calculated motion score is greater than the predetermined motion score threshold, image frame N+1 may be identified as having excessive motion and discarded, and processing may proceed to step 94 via path 85. At step 94, stacked processing circuitry 50 may use the stored image data from image frame N in the initial accumulate-frame for an output image frame to be provided to external processing circuitry such as processing circuitry 18 (FIG. 1). In this example, the effective integration time of the output frame is equal to the integration time of image frame N (e.g., the capture integration time). In another suitable arrangement, rather than discarding image frame N+1, motion correction operations may be performed on image frame N+1 and motion corrected image frame N+1 may be combined with the accumulate-frame for the output image frame. In this way, stacked processing circuitry 50 may minimize motion artifacts in the output image while improving signal-to-noise ratio.

If the calculated motion score is less than or equal to the predetermined motion score threshold, image data from image frame N+1 may be processed and combined with the accumulate-frame as shown in steps 86, 88, and 90. In particular, processing may proceed to step 86 via path 87. At step 86, stacked processing circuitry 50 may conduct image enhancement on image frame N+1 using the motion information.

If desired, stacked processing circuitry 50 may perform super resolution interpolation using multiple captured image frames and the motion information. If stacked processing circuitry 50 detects subpixel motion in the captured image data, stacked processing circuitry 50 may perform intelligent interpolation such as normalized convolution to enhance image resolution.

At step 88, stacked processing circuitry 50 may align the additional image frame with the accumulate-frame. Processing circuitry 50 may align the additional image frame by rotating the current image frame so that objects in the current image frame align with corresponding objects in the accumulate-frame. For example, image frame N+1 may be aligned with image frame N. If desired, image frame N+1 may be aligned with any image frame. The image frame that frame N+1 is aligned to may sometimes be referred to as an anchor frame and may include, for example, image frame N, an accumulate image frame, or any other desired image frame with which to align subsequently captured image frames. If desired, the anchor frame may be selected as any frame of image data having the least amount of motion and the best focus detail of image frames captured by stacked-chip image sensor 16.

At step 90, stacked processing circuitry 50 may combine the aligned additional image frame with the accumulate-frame (e.g., by averaging pixel values from the additional image frame with pixel values from the accumulate-frame or by adding pixel values from the additional image frame to pixel values from the accumulate-frame and generating metadata containing the effective integration times for the accumulate frame). The combined frame may be stored in processing circuitry 50 as the new accumulate-frame. The accumulate-frame may have improved signal-to-noise ratio relative to each individually captured image frame (e.g., frame N or N+1) because the image data in the accumulate frame represents a larger effective integration time than that of an individual frame N or N+1. The accumulate-frame may have an effective integration time that is greater than the capture integration time (e.g., the accumulate-frame may have an effective integration time equal to a sum of the integration times of frames N and N+1).

At step 92, stacked processing circuitry 50 may compare the number of captured image frames to a predetermined maximum frame number MAX FRAMES. For example, processing circuitry 50 may compare N+1 to maximum frame number MAX_FRAMES. If the frame number (e.g., N+1) is less than maximum frame number MAX_FRAMES, processing may loop back to step 82 via path 93 to capture additional image frames for aligning and combining with the new accumulate-frame.

If the additional frame number (e.g., N+1) is greater than maximum frame number MAX_FRAMES, processing may proceed to step 94 via path 95. At step 94, stacked processing circuitry 50 may output the accumulate-frame from stacked-chip image sensor 16. The accumulate frame may have increased signal-to-noise ratio relative to an individual frame N and may be free from motion artifacts.

In another suitable arrangement, stacked processing circuitry may determine respective integration times for each pixel sub-array 31 in image pixel array 17. For example, stacked processing circuitry 50 may determine shorter integration times for pixel sub-arrays 31 having image data with a relatively high amount of motion and may determine longer integration times for pixel sub-arrays 31 having image data with a relatively low amount of motion. As another example, stacked processing circuitry 50 may determine shorter integration times for pixel sub-arrays 31 having relatively high light levels and may determine longer integration times for pixel sub-arrays 31 having relatively low light levels. Processing circuitry 50 may combine image data captured by each sub-array 31 to generate final combined image frames for outputting to external processing circuitry.

In this example, each pixel sub-array 31 in image pixel array 17 may have a different integration time. Stacked processing circuitry 50 may scale image pixel values in each output frame using the integration time that was used in capturing those image pixel value. However, this is merely illustrative.

If desired, stacked processing circuitry 50 may output the integration time of image pixel values in the output frame (e.g., the effective integration time may be output as metadata). For example, if pixel values from a particular sub-array in a combined frame have an integration time of 16 ms, metadata may also be provided that indicates the 16 ms integration time for that sub-array.

FIG. 8 is a flow chart of illustrative steps that may be used for determining individual integration times for different pixel sub-arrays 31 in image pixel array 17 using stacked processing circuitry 50. The steps of FIG. 8 may, for example, be performed by stacked processing circuitry 50 during step 72 of FIG. 5.

At step 101, stacked processing circuitry 50 may receive image data such as non-destructively sampled image data from pixel array 17.

At step 102, circuitry 50 may process the received image data and detect motion in a portion of the image data from pixel sub-arrays with moving objects. For example, stacked processing circuitry 50 may compute a motion score for image data from each pixel sub-array 31 and may compare the motion scores to a predetermined motion score threshold. The motion score may, for example, be calculated by comparing a particular sample of image data with a previously captured sample of image data or may be calculated by comparing a particular image frame with a previously captured image frame. Stacked processing circuitry 50 may identify pixel sub-arrays 31 having image data with excessive motion. Stacked processing circuitry 50 may determine relatively short integration times for pixel sub-arrays 31 having image data with detected motion (e.g., image data with a motion score that exceeds the predetermined motion score threshold). By selecting a relatively short integration time, processing circuitry 50 may reduce motion artifacts for that pixel sub-array 31 in subsequently captured image data.

At step 104, stacked processing circuitry 50 may process the received image data and determine that no motion is detected in other portions of the image data from pixel sub-arrays without moving objects. Circuitry 50 may determine relatively long integration times for pixel sub-arrays without moving objects (e.g., pixel sub-arrays having image data with a motion score that is less than the predetermined motion score threshold).

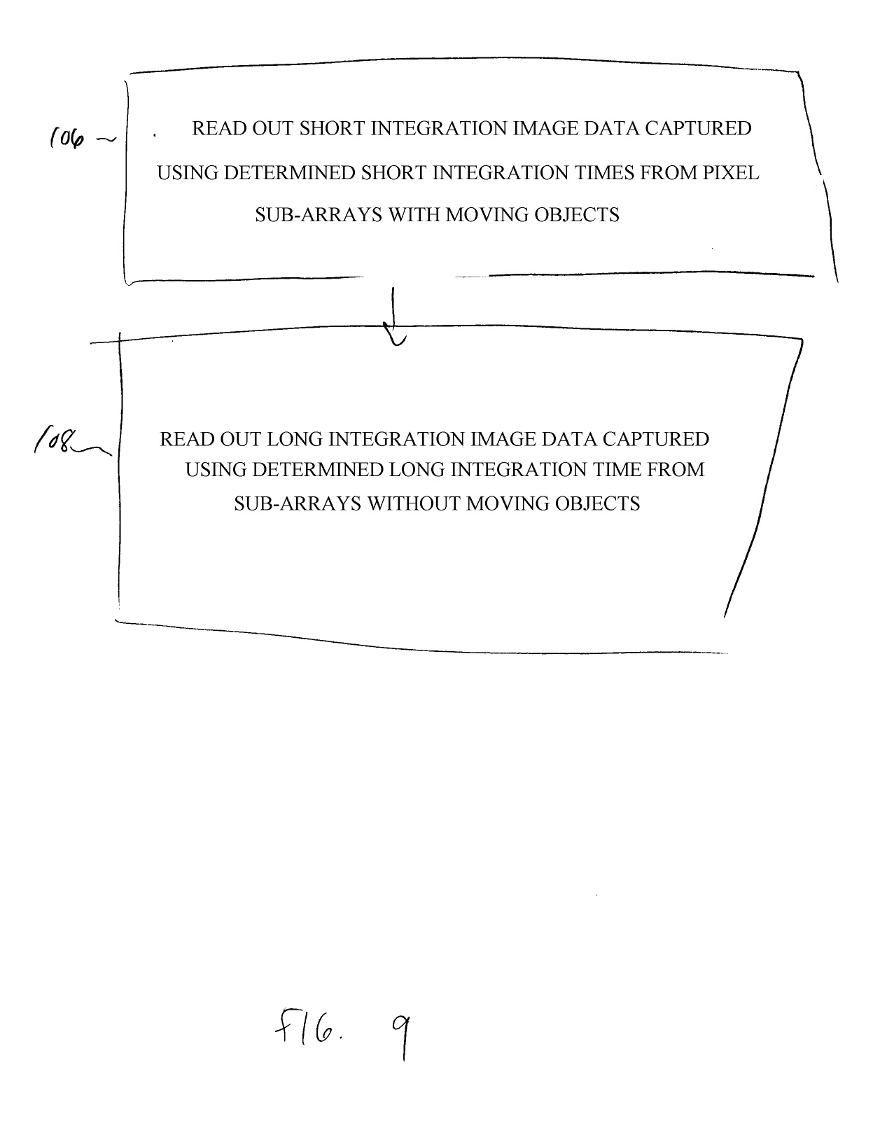

FIG. 9 is a flow chart of illustrative steps that may be performed by stacked processing circuitry 50 to combine image data captured by pixel sub-arrays 31 using different determined integration times. The steps of FIG. 9 may, for example, be performed by processing circuitry 50 during step 74 of FIG. 5.

At step 106, image data captured using the determined short integration times (e.g., short integration times as determined while processing step 102 of FIG. 8) may be read out from image pixel array 17 to stacked processing circuitry 50. If desired, processing circuitry 50 may receive multiple short integration image frames captured using the determined short integration time from a single pixel sub-array 31. In general processing circuitry 50 may receive short integration image frames having image data from any desired group of image pixels 30 in image pixel array 17.

At step 108, image data captured using the determined long integration time may be read out from image pixel array 17 to stacked processing circuitry 50 (e.g., long integration times as determined while processing step 104 of FIG. 8). For example, stacked processing circuitry 50 may receive long integration image data from pixel sub-arrays 31 without detected motion.

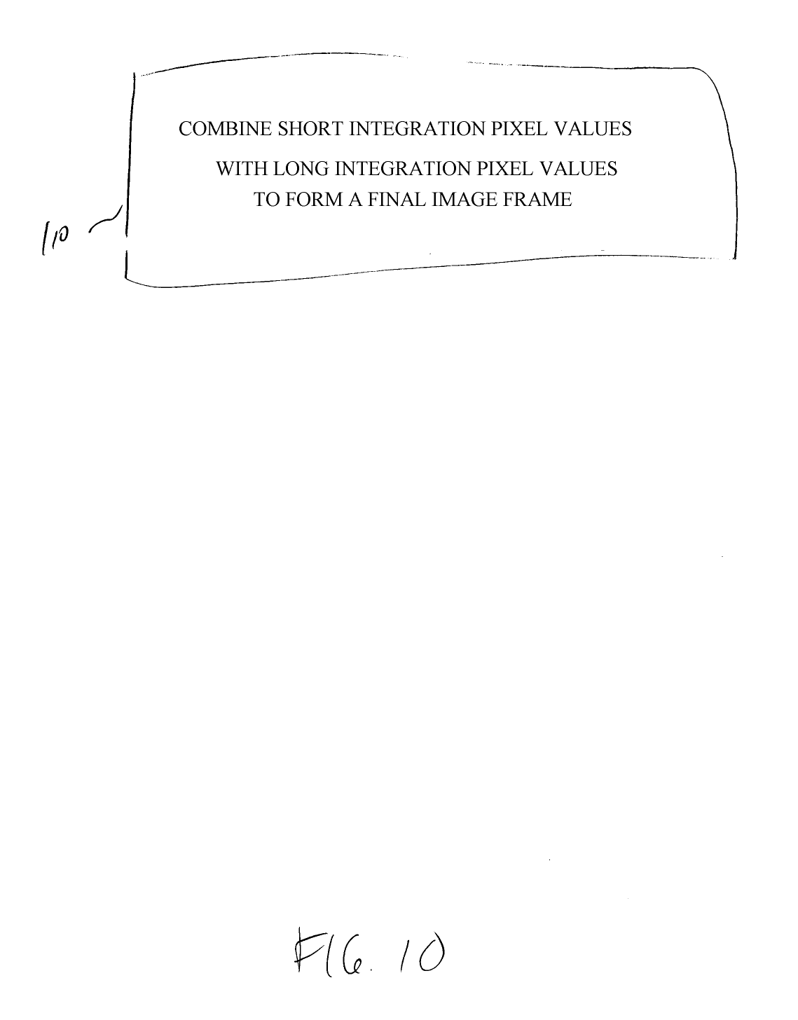

FIG. 10 is a flow chart that may be performed by stacked processing circuitry 50 to generate a final image frame from long integration image data and short integration image data. The step of FIG. 10 may, for example, be performed by stacked processing circuitry 50 while processing step 74 of FIG. 5.

At step 110, stacked processing circuitry 50 may combine short integration pixel values with long integration pixel values to generate a final image frame. For example, image data from pixel sub-arrays 31 captured during the determined long integration time may be combined with image data from pixel sub-arrays 31 captured during the determined short integration time.

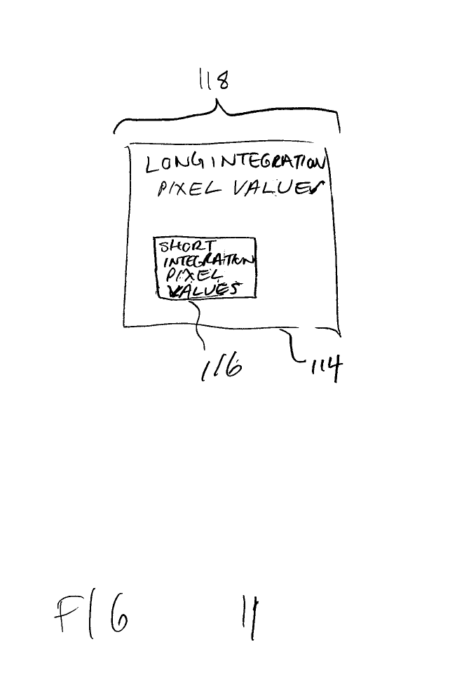

FIG. 11 is an illustrative diagram that shows how short integration pixel values may be combined with long integration pixel values to generate a final image frame for outputting from stacked-chip image sensor 16.

As shown in FIG. 11, final image frame 118 may include long integration pixel values 114 captured from a portion of a scene without motion during the determined long integration time and short integration pixel values 116 captured from a portion of the scene having moving objects during the determined short integration time. Image frame 118 may include one or more sets of short integration pixel values 116 from one or more pixel sub-arrays and one or more sets of long integration pixel values 114 from one or more pixel sub-arrays.

When capturing image data from low-light scenes, short integration pixel values 116 may not have sufficient signal-to-noise ratio to properly reflect the imaged scene. If desired, short-integration pixel values may be provided with an increased effective integration time by combining short-integration pixel values from multiple short integration image captures, thereby increasing the signal-to-noise ratio of final image frame 118.

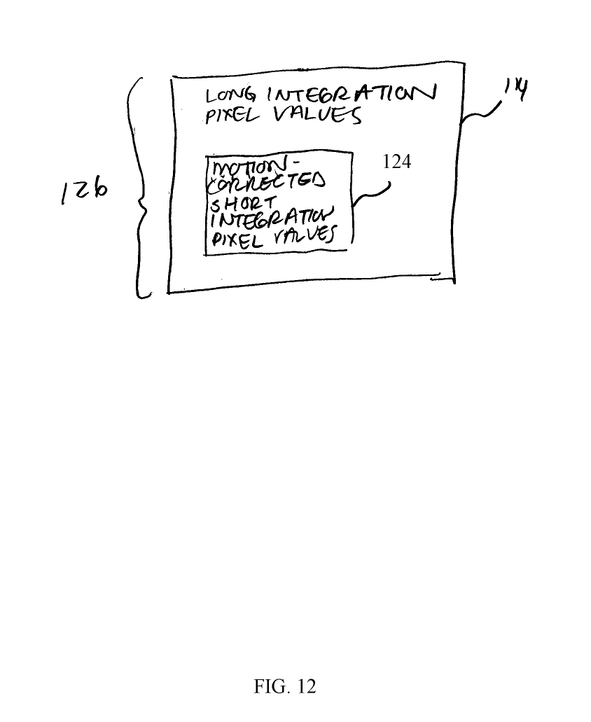

If desired, short-integration pixel values 114 may be processed to form motion corrected pixel values prior to output of image frame 118. FIG. 12 is an illustrative diagram that shows how motion-corrected short integration pixel values may be combined with long integration pixel values to generate the final image frame.

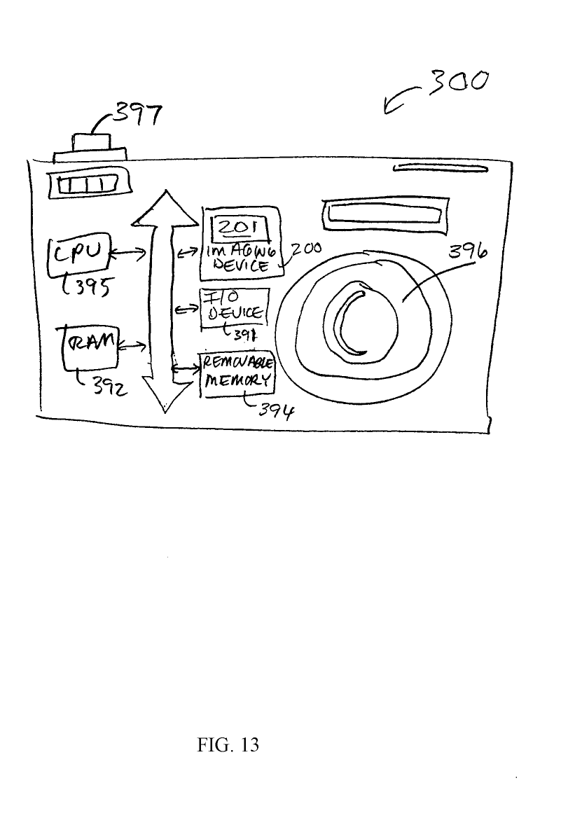

As shown in FIG. 13, final image frame 126 may include long integration pixel values 114 and motion-corrected short integration pixel values 124. Stacked processing circuitry 50 may perform motion correction operations on short integration image data to generate motion-corrected short integration pixel values 124. Motion-corrected short integration pixel values 124 may, for example, include multiple sets of short integration image data that have been aligned and combined with an anchor frame (e.g., multiple short integration image captures may be aligned and combined to generate motion-corrected short integration pixel values 124). Short integration pixel values 116 (FIG. 11) and motion-compensated short integration pixel values 124 may correspond to one or more pixel sub-arrays 31 in pixel array 17 or may correspond to any desired portion of image pixels 30 in pixel array 17.

If desired, choosing continuous integration times for pixel sub-arrays 31 may be combined with generating accumulate-frames having effective integration times (e.g., the steps of FIGS. 8-10 may be combined with the steps of FIG. 7). For example, stacked processing circuitry 50 may nondestructively sample image data during charge integration operations, determine short integration times for pixel sub-arrays with detected motion, and generate multiple short-exposure capture frames using the determined short integration time. In this way, stacked-processing circuitry 50 may generate output images with reduced read-out noise (by continuously integrating in motion regions for as long as possible) and reduced motion artifacts (by aligning and combining multiple short integration times) for the final output image frame.

FIG. 13 shows in simplified form a typical processor system 300, such as a digital camera, which includes an imaging device such as imaging device 200 (e.g., an imaging device 200 such as camera module 12 of FIG. 1 employing stacked storage and processing circuitry 50 and which is configured to capture images using selected integration times for each pixel sub-array 31 as described in connection with FIGS. 1-12). Processor system 300 is exemplary of a system having digital circuits that could include imaging device 200. Without being limiting, such a system could include a computer system, still or video camera system, scanner, machine vision, vehicle navigation, video phone, surveillance system, auto focus system, star tracker system, motion detection system, image stabilization system, and other systems employing an imaging device.

Processor system 300, which may be a digital still or video camera system, may include a lens such as lens 396 for focusing an image onto a pixel array such as pixel array 201 when shutter release button 397 is pressed. Processor system 300 may include a central processing unit such as central processing unit (CPU) 395. CPU 395 may be a microprocessor that controls camera functions and one or more image flow functions and communicates with one or more input/output (I/O) devices 391 over a bus such as bus 393. Imaging device 200 may also communicate with CPU 395 over bus 393. System 300 may include random access memory (RAM) 392 and removable memory 394. Removable memory 394 may include flash memory that communicates with CPU 395 over bus 393. Imaging device 200 may be combined with CPU 395, with or without memory storage, on a single integrated circuit or on a different chip. Although bus 393 is illustrated as a single bus, it may be one or more buses or bridges or other communication paths used to interconnect the system components.

Various embodiments have been described illustrating systems and methods for operating a stacked-chip image sensor having a planar array of image pixels and storage and processing circuitry. The stacked-chip image sensor may include a two-dimensional array of conductive metal vias coupled between the planar array of image pixels and the storage and processing circuitry. If desired, the stacked-chip image sensor may be coupled to off-chip image processing circuitry.

The planar array of image pixels may include a number of groups of image pixels (e.g., a number of pixel sub-arrays) that are each electrically coupled to the storage and processing circuitry through a respective conductive metal via in the two-dimensional array of conductive vias. Each group of image pixels may capture image data from a scene. The image data may be transferred to the storage and processing circuitry through the array of conductive vias (e.g., the storage and processing circuitry may sample or read out the image data from the groups of image pixels).

The storage and processing circuitry may process the image data to generate motion information for the image data corresponding to motion in the scene (e.g., the storage and processing circuitry may detect motion in the image data). For example, the storage and processing circuitry may generate respective motion scores for image data from each group of image pixels. The motion scores may be compared to a predetermined threshold to characterize the motion associated with image data from each group of image pixels.

The storage and processing circuitry may select respective integration times for each group of image pixels. For example, the storage and processing circuitry may identify relatively short integration times for groups of image pixels having image data with a motion score that exceeds the predetermined threshold and may identify relatively long integration times for groups of image pixels having image data with a motion score that is less than or equal to the predetermined threshold. If desired, the storage and processing circuitry may perform super resolution interpolation on the captured image data. The storage and processing circuitry may read out additional image data from the image sensor pixels after the selected integration time associated with the image sensor pixels. The storage and processing circuitry may read out respective image data from different pixel sub-arrays. The selected integration time may be less than an inverse of the output frame rate of the stacked-chip image sensor. The storage and processing circuitry may determine integration times for multiple pixel sub-arrays in parallel.

The storage and processing circuitry may generate an output image having multiple effective integration times using the motion information (e.g., having a respective integration time for each pixel sub-array). Image data captured by the groups of image pixels using the associated integration times may be combined to generate a combined frame. The combined frame may, for example, include pixel values from a long integration frame (e.g., pixel values from a long integration portion of an image) and pixel values from one or more short integration frames (e.g., pixel values from a short integration portion of an image). Multiple short integration frames may be aligned to an anchor frame and combined. The combined frame may be output from the stacked-chip image sensor.

If desired, the image data may be captured from the scene at a capture frame rate. Combined image frames and other image data may be output from the stacked-chip image sensor at an output frame rate that is less than the capture frame rate (e.g., the capture frame rate may be at least twice the output frame rate).

The stacked-chip image sensor and associated stacked storage and processing circuitry for determining integration times for capturing image data using pixel sub-arrays prior to outputting image data from the stacked-chip image sensor may be implemented in a system that also includes a central processing unit, memory, input-output circuitry, and an imaging device that further includes a lens for focusing light onto the array of image pixels in the stacked-chip image sensor, and a data converting circuit.

The foregoing is merely illustrative of the principles of this invention and various modifications can be made by those skilled in the art without departing from the scope and spirit of the invention. The foregoing embodiments may be implemented individually or in any combination.

What is claimed is:

1. A method for operating a stacked-chip image sensor, wherein the stacked-chip image sensor comprises a planar array of image sensor pixels, an array of vertical conductive vias, and processing circuitry coupled to the planar array of image sensor pixels through the array of vertical conductive vias, the method comprising:
with a portion of the image sensor pixels, capturing a first set of image data;
with the processing circuitry, determining an integration time for the portion of the image sensor pixels based on the first set of image data; and
with the processing circuitry, reading out a second set of image data from the portion of the image sensor pixels through the array of vertical conductive vias after the determined integration time.

2. The method defined in claim 1, further comprising:
with an additional portion of the image sensor pixels, while capturing the first set of image data, capturing a third set of image data; and
with the processing circuitry, determining an additional integration time for the additional portion of the image sensor pixels based on the third set of image data.

3. The method defined in claim 2, further comprising:
with the processing circuitry, reading out a fourth set of image data from the additional portion of the image sensor pixels through the array of vertical conductive vias after the determined additional integration time.

4. The method defined in claim 3 wherein the determined integration time is different than the additional determined integration time.

5. The method defined in claim 4 wherein reading out the second set of image data from the portion of the image sensor pixels through the array of vertical conductive vias comprises reading out the second set of image data from the portion of the image sensor pixels through a vertical conductive via in the array of vertical conductive vias that is associated with the portion of the image sensor pixels.

6. The method defined in claim 5 wherein reading out the fourth set of image data from the additional portion of the image sensor pixels through the array of vertical conductive vias comprises reading out the fourth set of image data from the additional portion of the image sensor pixels through an additional vertical conductive via in the array of vertical conductive vias that is associated with the additional portion of the image sensor pixels.

7. The method defined in claim 3, further comprising:
generating an output image that includes the second set of image data and the fourth set of image data.

8. The method defined in claim 7, further comprising:
outputting the output image and additional output images at an output frame rate.

9. The method defined in claim 8 wherein the integration time and the additional integration are both less than an inverse of the output frame rate.

10. The method defined in claim 1, further comprising:
detecting motion in the first captured set of image data.

11. The method defined in claim 10 wherein determining the integration time for the portion image sensor pixels based on the first set of image data comprises determining the integration time for the portion image sensor pixels based on the detected motion.

12. A method for operating a stacked-chip image sensor, wherein the stacked-chip image sensor comprises a planar array of image sensor pixels, an array of vertical conductive vias, and processing circuitry coupled to the planar array of image sensor pixels through the array of vertical conductive vias, the method comprising:
with the image sensor pixels, capturing a first set of image data;
providing the captured first set of image data to the processing circuitry using the array of vertical conductive vias;
with the processing circuitry, storing the first set of image data;
with the image sensor pixels, capturing a second set of image data;
with the processing circuitry, determining a motion score for the second set of image data by comparing the second set of image data to the stored first set of image data; and
with the processing circuitry, generating an output image having multiple effective integration times using the determined motion score.

13. The method defined in claim 12 wherein capturing the first set of image data comprises capturing the first set of image data during a capture integration time.

14. The method defined in claim 13 wherein at least one of the multiple effective integration times is equal to the capture integration time.

15. The method defined in claim 13 wherein at least one of the multiple effective integration times is at least twice the capture integration time.

16. The method defined in claim 13 wherein capturing the second set of image data comprises capturing the second set of image data during the capture integration time, the method further comprising:
comparing the determined motion score to a threshold; and
in response to determining that the motion score is less than the threshold, combining the second set of image data with the stored first set of image data.

17. The method defined in claim 13 wherein capturing the second set of image data comprises capturing the second set of image data during the capture integration time, the method further comprising:
comparing the determined motion score to a threshold; and
in response to determining that the motion score is greater than the threshold, using the stored first set of image data as a portion of the output image.

18. The method defined in claim 13 wherein the planar array of image sensor pixels comprises a first sub-array of image pixels and a second sub-array of image pixels, wherein the multiple effective integration times include a first effective integration time associated with the first sub-array of image pixels and a second effective integration time associated with the second sub-array of image pixels, and wherein the first effective integration time and the second effective integration time are integer multiples of the capture integration time.

19. A system, comprising:
a central processing unit;
memory;
input-output circuitry; and
an imaging device, wherein the imaging device comprises:
a stacked-chip image sensor having a pixel array and storage and processing circuitry that is vertically displaced from the pixel array;
image processing circuitry coupled to the stacked-chip image sensor through an array of conductive vias; and
a lens that focuses an image onto the pixel array, wherein a portion of the image sensor pixels is configured to capture a first set of image data, wherein the processing circuitry is configured to determine an integration time for the portion of the image sensor pixels based on the first set of image data, and wherein the processing circuitry is configured to read out a second set of image data from the portion of the image sensor pixels through the array of vertical conductive vias after the determined integration time.

20. The system defined in claim 19, wherein an additional portion of the image sensor pixels is configured to capture a third set of image data while the portion of image sensor pixels captures the first set of image data, wherein the processing circuitry is configured to determine an additional integration time for the additional portion of the image sensor pixels based on the third set of image data, wherein the processing circuitry is configured to read out a fourth set of image data from the additional portion of the image sensor pixels through the array of vertical conductive vias after the determined additional integration time, and wherein the determined integration time is different from the additional determined integration time.
